(19) United States
(12) Patent Application Publication
(10) Pub. No.: US 2025/0210894 A1
(43) Pub. Date: Jun. 26, 2025

(54) GRID ARRAY ELECTRICAL CONNECTORS

(71) Applicant: Intel Corporation, Santa Clara, CA (US)

(72) Inventors: Arturo PACHON MUNOZ, San Jose, CA (US); Oluwafemi AKINWALE, Hayward, CA (US); Howard HECK, Tigard, OR (US); Zhichao ZHANG, Chandler, AZ (US); Saikat MONDAL, Chandler, AZ (US)

(21) Appl. No.: 18/396,062

(22) Filed: Dec. 26, 2023

(51) Int. Cl. H01R 12/71; H01L 23/498; H01R 12/52; H01R 13/24; H05K 1/11; H05K 3/34

(52) U.S. Cl. CPC H01R 12/712; H01L 23/49811; H01L 23/49838; H01R 12/52; H01R 13/2492; H05K 1/112; H05K 3/3436; H01L 2223/64

(57) ABSTRACT

Electrical connectors for a semiconductor device package to a circuit board are provided. The electrical connectors can include interconnections having a first resistance that is greater than a second resistance. Assemblies are provided that include an electrical connector and a circuit board. Assemblies can also include a semiconductor device package. The assemblies provide connections to ground on the circuit board that have a higher resistance than connections for signal input output.

### FIELD

Descriptions are generally related to electrical socket and connector designs for attaching packaged semiconductor chips to circuit boards and more specifically to grid array sockets and connectors.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Because of ever-increasing signaling speed in electrical sockets and connectors, the socket and connector height and electrical lengths need be reduced in order to avoid resonance within signaling frequency of interest. Resonances will cause significant loss and crosstalk degradation. The need to reduce the socket and connector height creates significant mechanical and manufacturing challenges. Mechanical limitations associated with socket height reduction, include maintaining the compression forces needed to produce a reliable electrical mechanical connections.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention. Additionally, features are not necessarily illustrated relatively to scale due in part to the small sizes of some features and the desire for clarity of explanation in the figures.

FIG. 1 illustrates a package connected to a circuit board through a grid array connector.

FIGS. 2A-2B show an assembly which includes a land grid array connector.

FIGS. 3A-3B show an assembly which includes a pin grid array connector.

FIG. 4 illustrates a section of an example pin map for a semiconductor chip package.

FIGS. 5A-5B show examples where a series resistance is added to a ground trace between a semiconductor chip and a circuit board.

FIG. 6 shows an additional example in which a series resistance is added to ground traces between a semiconductor chip and the ground path of a circuit board.

FIG. 7 provides an exemplary computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), digital signal processors (DSPs), etc.), embedded controllers, or hardwired circuitry).

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, and/or semiconductor chip are interchangeable and refer to a semiconductor device comprising integrated circuits.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and other dies and/or a motherboard, a mainboard, a logic board, or a printed circuit board (PCB) for I/O (input/output) communication and power delivery. A package with multiple dies can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

In further examples of a package substrate core, the substrate core is a glass core comprising a solid amorphous glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, exemplary solid amorphous glass substrate cores can be considered to have a rectangular prism volume. The rectangular prism volume can contain vias that have been filled with one or more different materials. A material in a via can be a conducting metal such as copper. Exemplary solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example, the substrate core can be 10 mm by 10 mm up to 250 mm by 250 mm in two dimensions, but substrate cores do not necessarily have to have the same value in both dimensions.

Flow diagrams as illustrated herein provide examples of sequences of various process actions. The flow diagrams can indicate operations to be executed by a software or firmware routine, as well as physical operations. Physical operations can be performed by semiconductor processing equipment. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-K dielectrics, SiO₂, silicon nitride (SiN), silicon carbide (SiC), and/or silicon carbonitride (SiCN). Low-K dielectrics include for example, fluorine-doped SiO₂, carbon-doped SiO₂, porous SiO₂, porous carbon-doped SiO₂, combinations for the foregoing, and also these materials with airgaps. Dielectric layers that include conducting features can be intermetal dielectric (ILD) features.

Stamped and formed land grid array (LGA) sockets that have a height of about 2 mm produce crosstalk within frequencies of interest. For example, this crosstalk limits the usage of a LGA for ETH100G, a 100 gigabit/see Ethernet link, which is a product designed for PCIe 6.0/ETH50G (Peripheral Component Interconnect Express 50 gigabit/see Ethernet link) and lower throughput links. A resonance cavity created by an input/output (I/O) open structure in which the socket height of signal and GND (ground) sockets resonates and produce a low loss mechanism for exchanging the energy between aggressors and victim nearby pairs. Beyond resonance, the level of near-end crosstalk (NEXT) exceeds significantly what is required at a system level. The broadband NEXT trend changes substantially above 26 GHz and the signal to noise ratio is reduced significantly and consequently system performance is also reduced. The change in crosstalk performance is produced by a resonance cavity that is defined by the height of the socket and the signal to ground structures among the victim and disturber pairs.

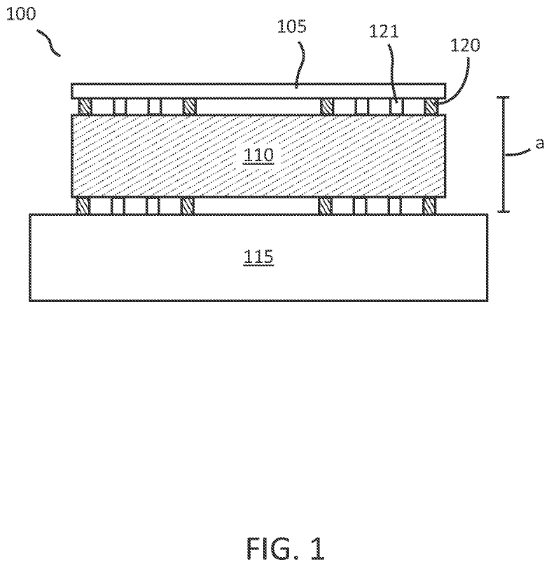

FIG. 1 shows a simplified view of an assembly for a packaged semiconductor device attached to a circuit board. The semiconductor device assembly 100 includes a packaged semiconductor device 105, a grid array electrical connector 110, and a circuit board 115. The semiconductor device can be one semiconductor chip or a plurality of semiconductor chips that are packaged together into one package unit. The grid array electrical connector 110 can include, for example, a land grid array (LGA) or a pin grid array (PGA) electrical connector. The LGA connector can be a stamped and formed LGA connector. Stamped and formed can be a manufacturing process where the connectors are stamped out of a sheet of flat metal and formed to the desired shape. The assembly also includes interconnects 120 and 121. Interconnects 120 connect to ground (GND) and interconnects 121 that transmit signals (I/O) (e.g., Tx and Rx) for the chip or plurality of semiconductor chips within the packaged semiconductor device 105. The interconnects 121 can be HSIO. The interconnects 121 also can be, for example, differential pairs. If the grid array connector 110 is a compressed grid array connector, it can have a height, indicated by “a” in FIG. 1, of, for example, 1 mm to 3 mm or 1.5 mm to 2.5 mm.

The circuit board 115 can be, for example, a motherboard, a printed circuit board, a system board, a logic board, a main board, or a board (which can sometimes be used interchangeably). The circuit board 115 can include a power supply that can control the amount of current and/or voltage going to components of the circuit board 115, such as the amount of current and/or voltage supplied to the packaged semiconductor device 105. The circuit board 115 can also provide interconnections processors and other computing devices and memory, such as DRAM.

The grid array electrical connector 110 can have a housing that is, for example, comprised of a lossy dielectric material, such as a material with a dissipation factor (DF)>0.1. The lossy dielectric materials can be located in regions of the housing. The lossy dielectric material can be one that exhibits a bulk conductivity of less than 10⁴ Siemens/meter. The housing can be a molded plastic with regions of lossy materials. The lossy materials can be binder with a conductive filler. Materials with a DF>0.1 include epoxies filled with metal nanoparticles such as silver nanoparticles, epoxies filled with carbon flakes or tubes, and lossy conductive materials. Lossy conductive materials include carbon or graphite fibers or materials that have particles or regions that do not provide high conductivity. The housing can also be a dielectric material, such as a plastic or a molded plastic or a ceramic. Other housing materials are also possible.

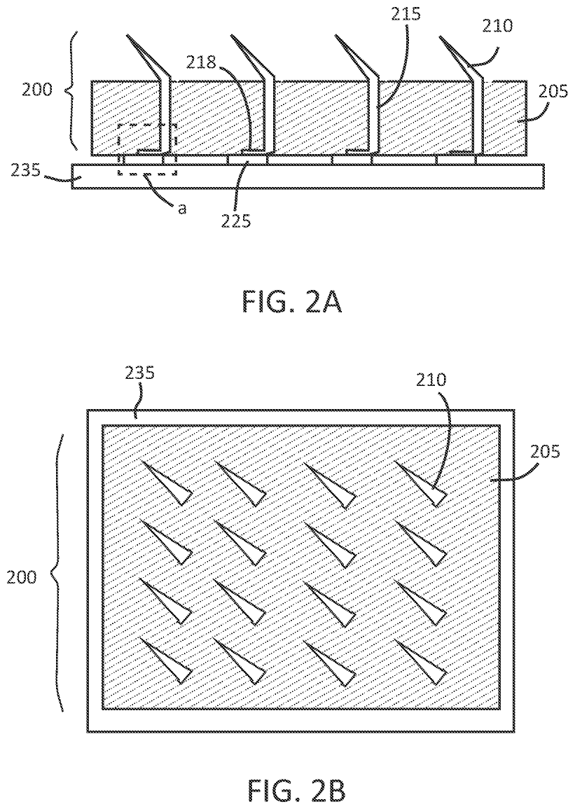

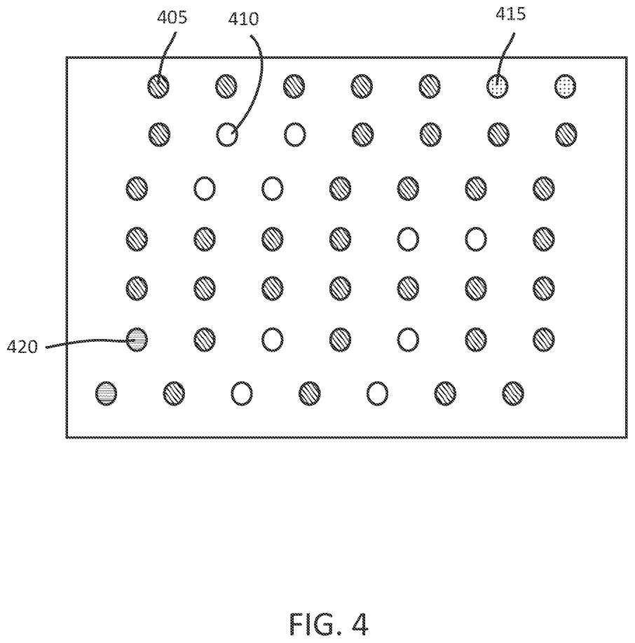

FIGS. 2A-2B provide illustrations of LGA assemblies. FIG. 2A is a cross sectional side view of an LGA electrical connector 200 assembly and FIG. 2B is a surface view of an LGA electrical connector 200 assembly. The LGA assemblies of FIG. 2A-2B can be further assembled to include an operably coupled semiconductor device package, such as the assembly that includes semiconductor device package 105 shown in and described with respect to FIG. 1. In FIGS. 2A-2B, an exemplary land grid array connector 200 includes a housing 205, conducting land contacts 210, conducting vias 215, and conducting connection region 218. The conducting land contacts 210, conducting vias 215, and conducting connection region 218 can be all one structure having been made using a stamp and form process. The LGA 200 is connected to a circuit board 235 by interconnections 225. The housing 205 can be a dielectric material, such as an insulating plastic or polymer, ceramic, and/or a liquid crystal polymer (LCP). The housing 205 can be formed through a molding process. The housing 205 can be, for example, a molded plastic or the housing 205 can be the housing 110 described with respect to FIG. 1. Conducting materials for land contacts 210, conducting vias 215, and conducting connection regions 218, include conducting metals such as, for example, copper, copper alloys, International Annealed Copper Standard (IACS) 40 copper clad steel, (such as copper beryllium alloys, and/or iron copper alloys. Land contacts 210 are resilient structures that can spring back after bending and are able to undergo deflections. Land contacts 210 that transmit signals can be comprised of a metal conductor that can exhibit a bulk conductivity of greater than 10⁴ siemens/meter to 108 seimens/meter. An LGA connector 200 can also include a mechanism (not shown) for holding a semiconductor chip package lands against the land contacts 210 so that electrical contact is maintained. The LGA connector 200 includes conducting land contacts 210 that are signal contacts and ones that are GND contacts. FIG. 4 provides a pin map showing example locations of GND pins, high-speed IO (HSIO), power delivery (PD), and test contacts. Land contacts 210 that are signal contacts can be, for example, differential pairs.

Land contacts 210 that are GND contacts can be comprised of a material that is different from that of other land contacts 210. The GND land contact 210 can be comprised of a material that has a lower conductivity than other land contacts 210, such as land contacts 210 that transmit signals. The GND land contacts 210 can be comprised of a lossy conductive material having a bulk conductivity of less than 10⁴ siemens/meter, or a lossy conductive material having a bulk conductivity of 10⁻¹ to 10⁴ siemens/meter. Lossy conductive materials include alloys of metals, such as, for example alloys of copper, alloys of iron and copper, and alloys of iron. The alloys can comprise, for example, beryllium. Lossy conductive materials can be materials with particles and/or regions (such as regions of particles or regions of a second material) that provide lower conductivity than the surrounding material. The GND land contacts 210 can have a resistance of between 1 Ohm and 40 Ohm, between 5 Ohm and 35 Ohm, or between 10 Ohm and 30 Ohm. Acceptable resistance values depend in part on the relative number of GND contacts versus signal transmission contacts.

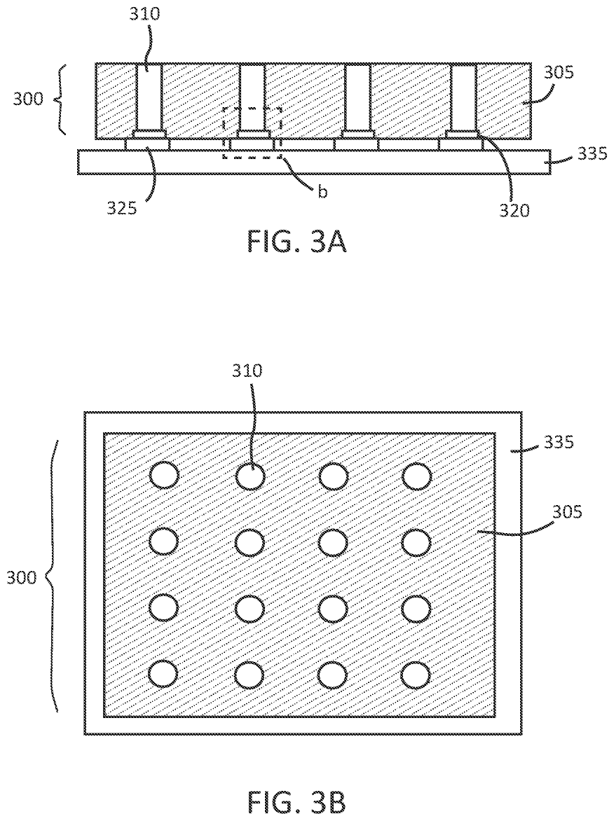

FIGS. 3A-3B show views of an assembly which includes a socket for PGAs 300. FIG. 3A is a cross sectional side view of a PGA electrical connector 300 and FIG. 3B is a surface view of an PGA electrical connector 300. The PGA assemblies of FIG. 3A-3B can be further assembled to include a semiconductor device package, such as the semiconductor device package 105 shown in and described with respect to FIG. 1. In FIGS. 3A-3B, an exemplary pin grid array electrical connector 300 includes a housing 305, pin receiving cavities 310, conducting pin receiving cavity landing pads 320. The PGA electrical connector 300 is connected to a circuit board 335 by interconnections 325. The housing 305 can be a dielectric material, such as an insulating plastic or polymer, ceramic, and/or a liquid crystal polymer (LCP). The housing 305 can be, for example, a molded plastic or the housing 305 can be the housing 110 described with respect to FIG. 1.

Pin receiving cavities 310 that receive GND pins can be comprised of a material that is different from that of other pin receiving cavities 310. The GND pin receiving cavities 310 can be comprised of a material that has a lower conductivity than other pin receiving cavities 310, such as in receiving cavities 310 for signal transmission. The pin receiving cavities 310 can be comprised of a lossy conductive material having a bulk conductivity of less than 10⁴ siemens/meter, or a lossy conductive material having a bulk conductivity of 10⁻¹ to 10⁴ siemens/meter. Lossy conductive materials include alloys of metals, such as, for example alloys of copper, alloys of iron and copper, and alloys of iron. The alloys can comprise, for example, beryllium. Lossy conductive materials can be materials with particles and/or regions (such as regions of particles or regions of a second material) that provide lower conductivity than the surrounding material. The GND pin receiving cavities 310 can have a resistance of between 1 Ohm and 40 Ohm, between 5 Ohm and 35 Ohm, or between 10 Ohm and 30 Ohm. Acceptable resistance values depend in part on the relative number of GND contacts versus signal transmission contacts.

FIG. 4 shows an example pin map for a semiconductor package lands (or pins) that can connect to land contacts or pin receiving cavities of a grid array connector, such as those of FIGS. 2A-2B and 3A-3B. Semiconductor package lands include GND lands 405, signal lands 410, power delivery lands 415, and test lands 420. Lands 405, 410, 415, and 420 could also be in the form of pins. Signal lands 410 that are co-located can be differential pairs of signals. The series resistances described herein, for example, with respect to FIGS. 1, 2A-2B, 3A-3B, and FIG. 6 can be on one, any number of, or all the ground traces for a semiconductor device package.

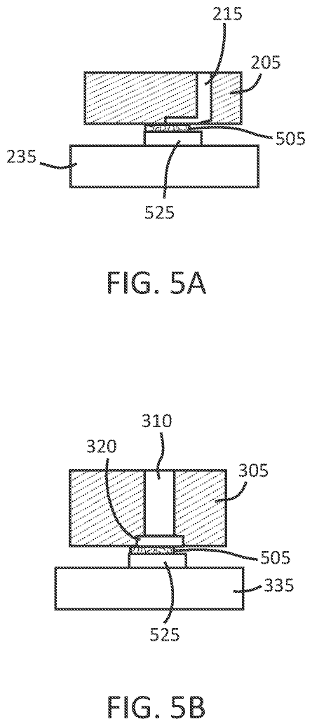

FIGS. 5A-5B provide examples where a series resistance has been added to a GND trace. FIG. 5A illustrates a section of FIG. 2A indicated by a dashed line labeled “a” and FIG. 5B illustrates a section of FIG. 3A indicated by a dashed line labeled “b.” Where the numbering of parts is the same for FIGS. 2A-2B and FIG. 5A, the descriptions herein with respect to FIGS. 2A-2B can be used for FIG. 5A. Where the numbering of parts is the same for FIGS. 3A-3B and FIG. 5B, the descriptions herein with respect to FIGS. 3A-3B can be used for FIG. 5B. Additionally, the examples of FIG. 5A-5B can be included in the assembly shown in and described with respect to FIG. 1. In FIG. 5A, the assembly includes a resistive region 505 conducting between connector via landing pads 218 and the circuit board ground connection region 525. The assembly of FIG. 5B also includes a resistive region 505 that is in series between the conducting pin receiving cavity landing pads 320 and the and the circuit board ground connection region 525. Although not shown, the assemblies can also include antipad regions that isolate landing pads 218, pin receiving cavity landing pads 320, and/or the circuit board ground connection 525.

The resistive region 505 can have a resistance of between 1 Ohm and 40 Ohm, between 5 Ohm and 35 Ohm, or between 10 Ohm and 30 Ohm. The resistive region 505 can be comprised of a resistive solder material or metallic paste. The resistive region 505 can be comprised of a silver paste. The silver paste can have silver particles that are in the form of spheres, flakes, and/or nanoparticles. The silver paste can also comprise a carrier, such as an organic polymer. Organic carriers include, for example, liquid poly (dimethlysiloxane). The silver paste can comprise less than 70% by weight of silver or less than 65% by weight of silver in a carrier before curing. The resistance of the silver paste can be tuned, for example, by mechanical turning, choice and ratio of types of silver particles (spheres, flakes, and/or nanoparticles), and choice of cure temperature and cure times. Other materials are possible.

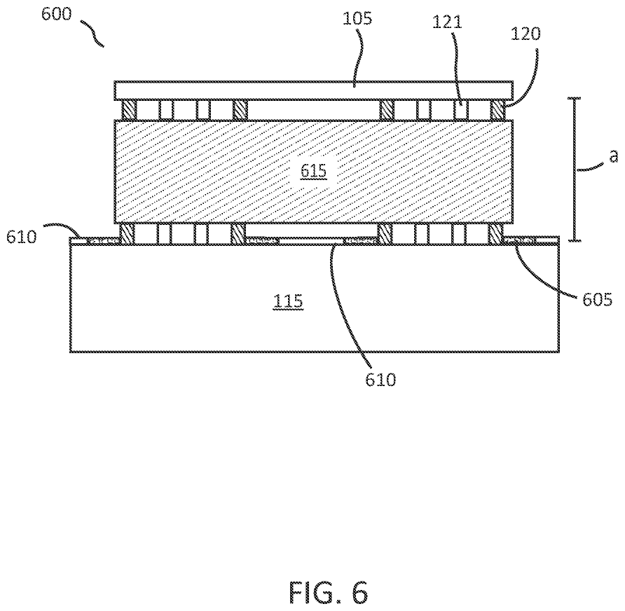

FIG. 6 illustrates a semiconductor chip package assembly 600 that includes a series resistance between the semiconductor package and the circuit board 115 ground 610 return traces. Where the numbering of parts is the same for FIG. 1 and FIG. 6, the descriptions herein with respect to FIG. 1 can be used for FIG. 6. The semiconductor device assembly 600 includes a packaged semiconductor device 105, a grid array connector 110, and a circuit board 115. The grid array connector 110 can include, for example, a land grid array (LGA) or a pin grid array (PGA) socket. The assembly also includes interconnects 120 and 121. Interconnects 120 connect to ground (GND) and interconnects 121 that transmit signals (I/O). The interconnects 121 can be HSIO. FIG. 4 provides a pin map showing example locations of GND pins, high-speed IO (HSIO), power delivery (PD), and test contacts in a semiconductor package and a corresponding connector. The housing 615 can be a dielectric material, such as an insulating plastic or polymer, ceramic, and/or a liquid crystal polymer (LCP). The housing 615 can be formed through a molding process. The housing 615 can be, for example, a molded plastic, a liquid crystal polymer (LCP), or the housing 615 can be the housing 110 described with respect to FIG. 1. The resistive region 605 can have a resistance of between 1 Ohm and 40 Ohm, between 5 Ohm and 35 Ohm, or between 10 Ohm and 30 Ohm. The resistive region 605 can be comprised of epoxy paste with conducting elements in the form of particles or flakes.

A high frequency signal can pass through degraded contact interfaces with DC resistance under about 2 Ohm without significant impact on signal integrity and performance. (As used herein “about” indicates +/−10% of the value indicated.) A high-speed connection with dedicated socket shields and with multiple points of contact (for example, with 8 surrounding differential socket pairs) creates a parallel ground resistance circuit, which can effectively mitigate the impact of any individual high resistance value at the ground interfaces. The result is a reduction in the overall effect of a high resistance for any given differential pair. For example, employing Equation 1 for 8 parallel resistances of 15 Ohm each:

1/Zₜₒₜₐₗ=1/Z₁+1/Z₂+1/Z₃+ . . . +1/Zₙ Equation 1

where Zₜₒₜₐₗ is the total resistance of the system of parallel resistances, Zₙ is the resistance of an individual parallel resistance, yields a total system resistance of 1.9 Ohms.

The circuit boards 235, 335, and 535 can be, for example, a motherboard, a printed circuit board, a system board, a logic board, a main board, or a board (which can sometimes be used interchangeably). The circuit board 235, 335, and 535 can include a power supply that can control the amount of current and/or voltage going to components of the circuit board 235, 335, and 535, such as the amount of current and/or voltage supplied to the packaged semiconductor device 105. The circuit board 115 can also provide interconnections processors and other computing devices and memory, such as DRAM.

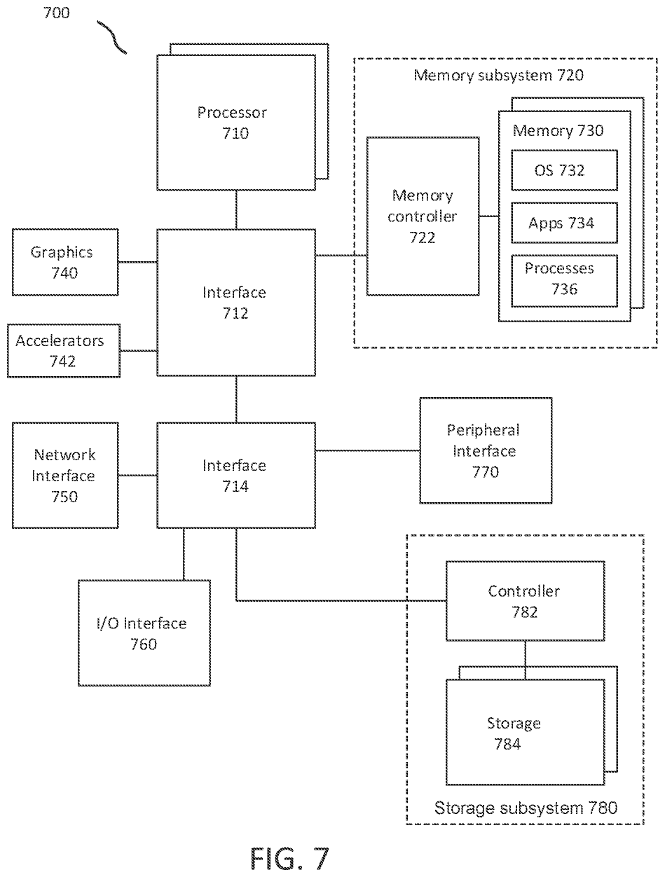

The semiconductor chips within semiconductor chip package 105 can be, for example, any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), high bandwidth memory (HBM), and/or other memory devices. The semiconductor chips within semiconductor chip package 105 can be any of the chips, for example, described herein with respect to FIG. 7. The semiconductor chip package 105 can for example, include a processor or a processor and memory.

FIG. 7 depicts an example computing system which can include any of the assemblies or connectors shown and described with respect to FIG. 1, 2A-2B, 3A-3B, 4, 5A-5C, and/or 6. A computing system 700 can include more, different, or fewer features than the ones described with respect to FIG. 7.

Computing system 700 includes processor 710, which provides processing, operation management, and execution of instructions for system 700. Processor 710 can include any type of microprocessor, CPU (central processing unit), GPU (graphics processing unit), processing core, or other processing hardware to provide processing for system 700, or a combination of processors or processing cores. Processor 710 controls the overall operation of system 700, and can be or include, one or more programmable general-purpose or special-purpose microprocessors, DSPs, programmable controllers, ASICs, programmable logic devices (PLDs), or the like, or a combination of such devices.

In one example, system 700 includes interface 712 coupled to processor 710, which can represent a higher speed interface or a high throughput interface for system components needing higher bandwidth connections, such as memory subsystem 720 or graphics interface components 740, and/or accelerators 742. Interface 712 represents an interface circuit, which can be a standalone component or integrated onto a processor die. Where present, graphics interface 740 interfaces to graphics components for providing a visual display to a user of system 700. In one example, the display can include a touchscreen display.

Accelerators 742 can be a fixed function or programmable offload engine that can be accessed or used by a processor 710. For example, an accelerator among accelerators 742 can provide data compression capability, cryptography services such as public key encryption (PKE), cipher, hash/authentication capabilities, decryption, or other capabilities or services. In some cases, accelerators 742 can be integrated into a CPU socket (e.g., a connector to a motherboard (or circuit board, printed circuit board, mainboard, system board, or logic board) that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 742 can provide multiple neural networks, CPUs, processor cores, general purpose graphics processing units, or graphics processing units can be made available for use by artificial intelligence (AI) or machine learning (ML) models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 730 stores and hosts, among other things, operating system (OS) 732 that provides a software platform for execution of instructions in system 700, and stores and hosts applications 734 and processes 736. In one example, memory subsystem 720 includes memory controller 722, which is a memory controller to generate and issue commands to memory 730. The memory controller 722 can be a physical part of processor 710 or a physical part of interface 712. For example, memory controller 722 can be an integrated memory controller, integrated onto a circuit within processor 710.

System 700 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 700 includes interface 714, which can be coupled to interface 712. In one example, interface 714 represents an interface circuit, which can include standalone components and integrated circuitry. In one example, user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB, or other wired or wireless standards-based or proprietary interfaces. Network interface 750 can transmit data to a device that is in the same data center or rack or a remote device, which can include sending data stored in memory.

Some examples of network interface 750 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include additional types of hardware interfaces, such as, for example, interfaces to semiconductor fabrication equipment and/or electrostatic charge management devices.

In one example, system 700 includes storage subsystem 780. Storage subsystem 780 includes storage device(s) 784, which can be or include any conventional medium for storing data in a nonvolatile manner, such as one or more magnetic, solid state, and/or optical based disks. Storage 784 can be generically considered to be a “memory,” although memory 730 is typically the executing or operating memory to provide instructions to processor 710. Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 712 or processor 710 or can include circuits or logic in both processor 710 and interface 714.

A power source (not depicted) provides power to the components of system 700. More specifically, power source typically interfaces to one or multiple power supplies in system 700 to provide power to the components of system 700.

Exemplary systems may be implemented in various types of computing, smart phones, tablets, personal computers, and networking equipment, such as switches, routers, racks, and blade servers such as those employed in a data center and/or server farm environment.

### Examples

An electrical connector for a semiconductor device package can comprise: a housing wherein the housing can be comprised of a dielectric material, wherein the housing has a first surface on a first side of the housing and a second surface on a second side of the housing, and wherein the first side of the housing can be opposite the second side of the housing; a first electrical contact wherein a first region of the first electrical contact protrudes above the first surface of the housing and a second region of the first electrical contact extends through the housing; and a second electrical contact wherein a first region of the second electrical contact protrudes above the first surface of the housing and a second region of the second electrical contact extends through the housing, wherein the first electrical contact has a resistance and the second electrical contact has a resistance and the resistance of the first electrical contact can be greater than the resistance of the second electrical contact, and wherein there are a plurality of first electrical contacts and a plurality of second electrical contacts arrayed in the housing. The resistance of the first electrical contact can be between 1 Ohm and 40 Ohm. The resistance of the first electrical contact can be between 10 Ohm and 30 Ohm. The first electrical contact can be comprised of a lossy conductive material having a bulk conductivity of less than 10⁴ siemens/meter. The housing can be comprised of a molded plastic material. The first electrical contact can be positioned in the housing to provide a ground connection to a semiconductor device package.

A circuit board assembly can comprise: a circuit board; and an electrical connector comprising a first array of contacts on a first surface of the electrical connector wherein the first array of contacts are capable of electrically connecting the circuit board to a semiconductor device package, and a second array of contacts on a second surface of the electrical connector wherein the second array of contacts are electrically connected to the circuit board, wherein there can be an electrical connection between a first contact of the first array of contacts and a first contact of the second array of contacts, wherein the first contact of the second array of contacts can be electrically connected to a ground trace on the circuit board, and wherein there can be a resistance between the first contact of the first array of contacts and a ground on the circuit board and the resistance can be between 1 Ohm and 40 Ohm. The circuit board assembly can also comprise a solder region between the first contact of the second array of contacts and the circuit board and the solder region has a resistance of between 1 Ohm and 40 Ohm. The circuit board assembly can also comprise a second contact of the first array of contacts and a second contact of the second array of contacts, wherein there can be an electrical connection between the second contact of the first array of contacts and the second contact of the second array of contacts, and wherein the second contact of the second array of contacts can be electrically connected to a signal trace on the circuit board. The circuit board assembly can also comprise a solder region between the first contact of the second array of contacts and the circuit board and wherein the solder region comprises silver particles. The silver particles can be comprised of flakes, spheres, nanoparticles, or a combination thereof. The electrical connector can be a land grid array connector. The electrical connector can additionally comprise a housing that can be comprised of a liquid crystal polymer.

A semiconductor package assembly can comprise: a semiconductor device package having a plurality lands on a surface, wherein the semiconductor device package includes a semiconductor chip; an electrical connector; and a circuit board wherein the circuit board comprises a ground, wherein the semiconductor device package is operably connected to the electrical connector through the lands, wherein the electrical connector is operably connected to the circuit board, wherein a first land of the plurality of lands on the semiconductor device surface is connected the ground of circuit board, and wherein there is a first resistance between the first land of the plurality of lands on the semiconductor device surface and the ground of the circuit board and the first resistance is between 1 Ohm and 40 Ohm. The connector can comprise a conducting region, wherein the conducting region connects the first land of the plurality of lands to the ground of the circuit board, and wherein the conducting region has a resistance and the conducting region resistance can be between 1 Ohm and 40 Ohm. The first resistance can be between 5 Ohm and 35 Ohm. A second and third land of the plurality of lands can be for signals that are differential pairs. The semiconductor device package can comprise a processor. A second land of the plurality of lands can be for high speed input output. A second land of the plurality of lands can be for signals.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An electrical connector for a semiconductor device package comprising:
a housing wherein the housing is comprised of a dielectric material, wherein the housing has a first surface on a first side of the housing and a second surface on a second side of the housing, and wherein the first side of the housing is opposite the second side of the housing;
a first electrical contact wherein a first region of the first electrical contact protrudes above the first surface of the housing and a second region of the first electrical contact extends through the housing; and
a second electrical contact wherein a first region of the second electrical contact protrudes above the first surface of the housing and a second region of the second electrical contact extends through the housing,
wherein the first electrical contact has a resistance and the second electrical contact has a resistance and the resistance of the first electrical contact is greater than the resistance of the second electrical contact, and
wherein there are a plurality of first electrical contacts and a plurality of second electrical contacts arrayed in the housing.

2. The electrical connector of claim 1, wherein the resistance of the first electrical contact is between 1 Ohm and 40 Ohm.

3. The electrical connector of claim 1, wherein the resistance of the first electrical contact is between 10 Ohm and 30 Ohm.

4. The electrical connector of claim 1 wherein the first electrical contact is comprised of a lossy conductive material having a bulk conductivity of less than 10⁴ siemens/meter.

5. The electrical connector of claim 1 wherein the housing is comprised of a molded plastic material.

6. The electrical connector of claim 1 wherein the first electrical contact is positioned in the housing to provide a ground connection to a semiconductor device package.

7. A circuit board assembly comprising:
a circuit board; and
an electrical connector comprising a first array of contacts on a first surface of the electrical connector wherein the first array of contacts are capable of electrically connecting the circuit board to a semiconductor device package, and a second array of contacts on a second surface of the electrical connector wherein the second array of contacts are electrically connected to the circuit board,
wherein there is an electrical connection between a first contact of the first array of contacts and a first contact of the second array of contacts,
wherein the first contact of the second array of contacts is electrically connected to a ground trace on the circuit board, and
wherein there is a resistance between the first contact of the first array of contacts and a ground on the circuit board and the resistance is between 1 Ohm and 40 Ohm.

8. The circuit board assembly of claim 7 also comprising a solder region between the first contact of the second array of contacts and the circuit board and the solder region has a resistance of between 1 Ohm and 40 Ohm.

9. The circuit board assembly of claim 7 also comprising a second contact of the first array of contacts and a second contact of the second array of contacts, wherein there is an electrical connection between the second contact of the first array of contacts and the second contact of the second array of contacts, and wherein the second contact of the second array of contacts is electrically connected to a signal trace on the circuit board.

10. The circuit board assembly of claim 7 also comprising a solder region between the first contact of the second array of contacts and the circuit board and wherein the solder region comprises silver particles.

11. The circuit board assembly of claim 10 wherein the silver particles are comprised of flakes, spheres, nanoparticles, or a combination thereof.

12. The circuit board assembly of claim 7 wherein the electrical connector is a land grid array connector.

13. The circuit board assembly of claim 7 wherein the electrical connector additionally comprises a housing that is comprised of a liquid crystal polymer.

14. A semiconductor package assembly comprising:
a semiconductor device package having a plurality lands on a surface, wherein the semiconductor device package includes a semiconductor chip;
an electrical connector; and
a circuit board wherein the circuit board comprises a ground,
wherein the semiconductor device package is operably connected to the electrical connector through the lands,
wherein the electrical connector is operably connected to the circuit board, wherein a first land of the plurality of lands on the semiconductor device surface is connected the ground of circuit board, and
wherein there is a first resistance between the first land of the plurality of lands on the semiconductor device surface and the ground of the circuit board and the first resistance is between 1 Ohm and 40 Ohm.

15. The semiconductor package assembly of claim 14 wherein the electrical connector comprises a conducting region, wherein the conducting region connects the first land of the plurality of lands to the ground of the circuit board, and wherein the conducting region has a resistance and the conducting region resistance is between 1 Ohm and 40 Ohm.

16. The semiconductor package assembly of claim 14 wherein the first resistance is between 5 Ohm and 35 Ohm.

17. The semiconductor package assembly of claim 14 wherein a second and third land of the plurality of lands are for signals that are differential pairs.

18. The semiconductor package assembly of claim 14 wherein the semiconductor device package comprises a processor.

19. The semiconductor package assembly of claim 14 wherein a second land of the plurality of lands is for high speed input output.

20. The semiconductor package assembly of claim 14 wherein a second land of the plurality of lands is for signals.
